(19) United States
(12) Patent Application Publication
(10) Pub. No.: US 2025/0011594 A1
(43) Pub. Date: Jan. 9, 2025

(54) RESIN COMPOSITION AND ARTICLE MADE THEREFROM

(71) Applicant: ELITE MATERIAL CO., LTD., Taoyuan City (TW)

(72) Inventors: Shu-Hao CHANG, Taoyuan City (TW); Yueh-Fu LIN, Taoyuan City (TW)

(73) Assignee: ELITE MATERIAL CO., LTD., Taoyuan City (TW)

(21) Appl. No.: 18/232,281

(22) Filed: Aug. 9, 2023

(30) Foreign Application Priority Data
Jul. 7, 2023 (TW) 112125374

(51) Int. Cl. C08L 71/12; C08J 5/24; C08K 5/01; C08K 7/18; H05K 1/03

(52) U.S. Cl. CPC C08L 71/126; C08J 5/244; C08J 5/249; C08K 5/01; C08K 7/18; H05K 1/0373; C08J 2371/12; C08J 2425/00; C08L 2203/20; C08L 2205/025; C08L 2205/035; C08L 2312/00

(57) ABSTRACT

A resin composition is disclosed. The resin composition includes 100 parts by weight of vinyl group-containing polyphenylene ether, 20 parts by weight to 60 parts by weight of ethylene-styrene-divinylbenzene copolymer, and 5 parts by weight to 15 parts by weight of a compound represented by the Formula (1). An article made from the composition is also disclosed, and the article includes prepreg, resin film, laminate, or printed circuit board.

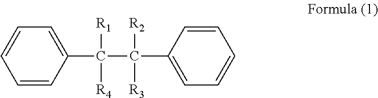

### CROSS-REFERENCE TO RELATED APPLICATIONS

This non-provisional application claims priority under 35 U.S.C. § 119(a) on Patent Application No. 112125374 filed in ROC on Jul. 7, 2023, the entire contents of which are hereby incorporated by reference.

### BACKGROUND

### 1. Technical Field

This present disclosure relates to a resin composition and article made therefrom.

### 2. Related Art

The operation of the electronic device is accomplished by the conductive circuits on the circuit board connecting a plurality of electronic components to supply electric power and to transmit signals. A circuit board is generally composed of a circuit substrate and conductive circuit patterns on the circuit substrate.

With the rapid development of fifth generation (5G) wireless system and the high function and compactness of electronic devices, the circuit board used therein has developed toward multiple-layer construction, high-density interconnection and high-speed signal transmission. Correspondingly, in order to ensure the quality of the electronic device, there is a higher demand for comprehensive performance of circuit substrates (such as copper-clad laminate).

Therefore, how to develop a material applicable to high-performance laminate is what the industry works hard for currently.

### SUMMARY

Accordingly, in view of the problems, particularly that conventional materials cannot satisfy the demand for the above one or more performances, encountered in the related art, this disclosure mainly aims at providing a resin composition and article made therefrom which are capable of satisfying the demand for the above performances.

This present disclosure provides a resin composition, comprising:
100 parts by weight of a vinyl group-containing polyphenylene ether resin;
20 parts by weight to 60 parts by weight of a divinylbenzene-styrene-ethylene terpolymer; and
5 parts by weight to 15 parts by weight of a compound represented by Formula (1),

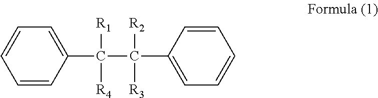

wherein each of R₁, R₂, R₃, and R₄ is independently a C1 to C4 alkylidene group or a hydrogen atom.

One embodiment of this disclosure provides an article made from the resin composition. The article comprises a prepreg, a resin film, a laminate, or a printed circuit board.

The article made from the resin composition of this disclosure, such as prepreg, resin film, laminate, or printed circuit board, has an excellent property of at least one of the copper foil peeling strength of a copper-containing laminate, water absorption rate, and dissipation factor. Therefore, the article can become a high-performance laminate satisfying the comprehensive demands.

### BRIEF DESCRIPTION OF THE DRAWINGS

The present disclosure will become better understood from the detailed description given hereinbelow and the accompanying drawings which are given by way of illustration only and thus are not intended to limit the present disclosure and wherein:

FIG. 1 is a schematic diagram of a laminate having a dry board appearance;

FIG. 2 is a schematic diagram of a laminate having a normal appearance;

FIG. 3 is a schematic diagram of a laminate with branch-like pattern; and

FIG. 4 is a schematic diagram of a laminate without branch-like pattern.

### DETAILED DESCRIPTION

The following embodiments describe detailed features and advantages of present disclosure in detail hereinafter, and the content is sufficient for those skilled in the art to understand the technical content of the present disclosure and to implement the present disclosure. According to the content, claims, and figures disclosed in the present disclosure, those skilled in the art can easily understand the relevant purposes and advantages of the present disclosure. The following embodiments further describe perspectives of the present disclosure in detail, but do not limit the scope of the present disclosure by any perspective.

In order to enable those skilled in the art to understand the features and effects of the present disclosure, the following mentioned terms and words in the specification and claims will generally be illustrated and defined. Unless otherwise specified, all technical and scientific words used herein have the common meaning as understood by those skilled in the art in regard to the present disclosure. It should be based on the definition in the specification when there is a conflict.

As used herein, the term “comprise,” “include,” “have,” “contain,” or the like belongs to the open-ended transitional phrase, intended to cover a non-exclusive inclusion. For example, a composition or article made therefrom includes a plurality of factors covering any one of the listed factors, which is not limited to the factors listed herein but may include other factors not clearly listed or usually inherent to such composition or article made therefrom. Besides, unless a contrary illustration presents clearly, the term “or” refers to an inclusive “or” not to an exclusive “or”. For example, any one of the following conditions satisfies the conditions “A or B”: A is true (or present) and B is false (or not present); A is false (or not present) and B is true (or present); and A and B are true (or present). Besides, the term “comprise,” “include,” “have,” “contain,” herein should be understood that close-ended transitional phrases such as “consisting of,” “composed by,” “remainder being,” and partially open-ended transitional phrases such as “consisting essentially,” “primarily consisting of,” “composed primarily by,” “basically containing,” “consisting basically of,” “composed basically by,” “essentially containing,” are also disclosed and included.

As used herein, the term “a composition comprises A, B, and C, wherein A comprises a1, a2, or a3” is same as “a composition comprises A, B, and C, wherein A comprises a1, a2, a3, or a combination thereof.” That is, “a composition comprises A, B, and C, wherein A comprises a1, a2, a3, a combination of a1 and a2, a combination of a1 and a3, a combination of a2 and a3, or a combination of a1, a2, and a3.”

As used herein, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein. For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0.

Given the intended purposes and advantages of this disclosure are achieved, numerals or figures have the precision of their significant digits. For example, 40.0 should be understood as covering a range of 39.50 to 40.49.

If not specified, in the present disclosure, a polymer refers to the product formed by monomer(s) via polymerization and includes multiple aggregates of polymers respectively formed by multiple repeated simple structure units by covalent bonds. The monomer refers to the compound forming the polymer. A polymer may include a homopolymer, a copolymer, a prepolymer, etc., but not limited thereto. A prepolymer refers to the chemical substance formed by two or more compounds via polymerization with a conversion rate between 10% and 90%. The term “polymer” includes but not limited to an oligomer. An oligomer, also known as low polymer, refers to a polymer with 2 to 20, typically 2 to 5, repeating units. For example, diene polymer is interpreted as including diene homopolymer, diene copolymer, diene prepolymer, and, of course, also including diene oligomer.

If not specified, in the present disclosure, a copolymer refers to the product formed by two or more different monomers via polymerization and includes but not limited to random copolymers, alternating copolymers, graft copolymers, or block copolymers. For example, styrene-butadiene copolymer is a product formed merely by two monomers of styrene and butadiene via polymerization. For example, styrene-butadiene copolymer includes but not limited to styrene-butadiene random copolymer, styrene-butadiene alternating copolymer, styrene-butadiene graft copolymer, or styrene-butadiene block copolymer. Styrene-butadiene block copolymer includes, for example, but not limited to the molecular structure of styrene-styrene-styrene-butadiene-butadiene-butadiene-butadiene after polymerization. Styrene-butadiene block copolymer includes, for example, but not limited to styrene-butadiene-styrene block copolymer. Styrene-butadiene-styrene block copolymer includes, for example, but not limited to the molecular structure of styrene-styrene-styrene-butadiene-butadiene-butadiene-butadiene-styrene-styrene-styrene after polymerization. Similarly, hydrogenated styrene-butadiene copolymer includes hydrogenated styrene-butadiene random copolymer, hydrogenated styrene-butadiene alternating copolymer, hydrogenated styrene-butadiene graft copolymer, or hydrogenated styrene-butadiene block copolymer. Hydrogenated styrene-butadiene block copolymer includes, for example, but not limited to hydrogenated styrene-butadiene-styrene block copolymer.

If not specified, “resin” as used herein is a common name of a synthetic polymer, and is interpreted as including monomer and its combination, polymer and its combination or a combination of monomer and its polymer, and not limited thereto. For example, “maleimide resin” as used herein is interpreted as including maleimide monomer, maleimide polymer, a combination of maleimide monomer, a combination of maleimide polymer, or a combination of maleimide monomer and maleimide polymer.

As used herein, the term “vinyl group-containing” is interpreted as including a vinyl group, a vinylene group, an allyl group, or (meth)acrylate group, wherein a vinyl group includes vinylbenzyl group.

If not specified, in the present disclosure, a modification includes a product derived from a resin with its reactive functional group modified, a product derived from a prepolymerization reaction of each resin and other resins, a product derived from crosslinking reaction of each resin and other resins, a product derived from a homopolymerization reaction of each resin, a product derived from copolymerizing each resin and other resins or the like. For example, a modification may include replacing the terminal hydroxyl group with terminal vinyl group via a chemical reaction, or obtaining a terminal hydroxyl group formed by a terminal vinyl group and a p-aminophenol via a chemical reaction.

If not specified, the unsaturated bonds as used herein refer to reactive unsaturated bonds, such as but not limited to unsaturated bonds capable of carrying out crosslinking reaction with other functional groups, such as but not limited to unsaturated C═C double bonds capable of carrying out crosslinking reaction with other functional groups.

If not specified, as used herein, when a specific example of a compound is expressed by using a “(substituent)”, it should be interpreted as including two situations of containing and not containing the substituent. For example, cyclohexane dimethanol di(meth)acrylate should be interpreted as including cyclohexane dimethanol diacrylate and cyclohexane dimethanol dimethacrylate, and (meth)acrylate should be interpreted as including acrylate and methacrylate.

If not specified, alkyl group as used herein is interpreted as including any isomers thereof. For example, propyl group is interpreted as including n-propyl group and isopropyl group.

It should be understood that each of the embodiments herein may be arbitrarily combined to form the technical solution of the present disclosure as long as there is no contradiction in the combination of these features.

If not specified, as used herein, part(s) by weight represents weight part(s) in any weight unit, such as but not limited to kilogram, gram, pound and so on. For example, 100 parts by weight of the maleimide resin may represent 100 kilograms of the maleimide resin or 100 pounds of the maleimide resin. If the resin solution includes solvent and resin, the parts by weight of the (solid-state or liquid-state) resin generally refers to the weight unit of the (solid-state or liquid-state) resin, which does not include the weight unit of the solvent in the solution, while the parts by weight of the solvent refers to the weight unit of the solvent.

The following embodiments are essentially merely exemplary, and are not intended to limit the present disclosure and its application. Besides, the present disclosure is not limited by any theory described in the prior art or contents of the invention or the following embodiments or examples. Unless otherwise specified, methods, reagents and conditions adopted in the embodiments are routine methods, reagents and conditions in the field.

One embodiment of this disclosure provides a resin composition, comprising 100 parts by weight of a vinyl group-containing polyphenylene ether resin, 20 parts by weight to 60 parts by weight of a divinylbenzene-styrene-ethylene terpolymer, and 5 parts by weight to 15 parts by weight of a compound represented by Formula (1).

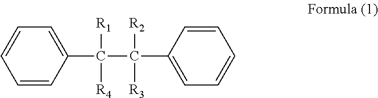

In Formula (1), each of R₁, R₂, R₃, and R₄ is independently a C1 to C4 alkylidene group or a hydrogen atom.

In one embodiment, the amount of the vinyl group-containing polyphenylene ether resin in the resin composition is 100 parts by weight, and the amount of other resins or additives is a relative amount, with respect to 100 parts by weight of the vinyl group-containing polyphenylene ether resin. For example, if not specified, the amount of the divinylbenzene-styrene-ethylene terpolymer of one embodiment of this disclosure is 20 parts by weight to 60 parts by weight, with respect to 100 parts by weight of the vinyl group-containing polyphenylene ether resin. For example, the resin composition in one embodiment of this disclosure may include 100 kilograms of the vinyl group-containing polyphenylene ether resin and 20 kilograms to 60 kilograms of the divinylbenzene-styrene-ethylene terpolymer. For example, the resin composition in one embodiment of this disclosure may include 100 pounds of the vinyl group-containing polyphenylene ether resin and 20 pounds to 60 pounds of the divinylbenzene-styrene-ethylene terpolymer.

In one embodiment, the vinyl group-containing polyphenylene ether resin may include various polyphenylene ether resins with their terminal modified by a vinyl group, an allyl group, or a vinylene group. The vinyl group-containing polyphenylene ether resin may include a vinylbenzyl-containing polyphenylene ether resin, a (meth)acrylate-containing polyphenylene ether resin, a vinylbenzyl-containing bisphenol A polyphenylene ether resin, or a maleimide-containing polyphenylene ether resin, and is not limited thereto. The vinyl group-containing polyphenylene ether resins with their terminal having a vinyl group, an allyl group, or a vinylene group can carry out polymerization reactions by unsaturated bonds.

In one embodiment, the vinyl group-containing polyphenylene ether resin may include various vinyl group-containing polyphenylene ether resins known in the field. The vinyl group-containing polyphenylene ether resin applicable to the present disclosure is not particularly limited, and may be any one or more of commercial products or homemade products. In some embodiments, any one or more of vinylbenzyl-containing biphenyl polyphenylene ether resin (such as OPE-2st, available from Mitsubishi Gas Chemical Co., Inc.), methacrylate-containing polyphenylene ether resin (such as SA9000, available from Sabic) and vinylbenzyl-containing bisphenol A polyphenylene ether resin may be used. However, this disclosure is not limited thereto.

In one embodiment, the divinylbenzene-styrene-ethylene terpolymer may be a product after polymerization reaction of three monomer raw materials including divinylbenzene, styrene, and ethylene. The divinylbenzene-styrene-ethylene terpolymer obtained by polymerization may be a random copolymer. That is, the three monomers, the divinylbenzene, the styrene, and the ethylene, are crosslinked with each other by irregular random arrangement. In another embodiment, the divinylbenzene among the monomer raw materials of the divinylbenzene-styrene-ethylene terpolymer may be p-divinylbenzene (i.e., para-divinylbenzene).

In one embodiment, a number average molecular weight (Mn) of the divinylbenzene-styrene-ethylene terpolymer may be between 5,000 and 15,000. In another embodiment, a number average molecular weight of the divinylbenzene-styrene-ethylene terpolymer may be between 5,000 and 11,000. In still another embodiment, a number average molecular weight of the divinylbenzene-styrene-ethylene terpolymer may be between 6,000 and 10,000.

In one embodiment, in the raw materials for polymerization reaction of the divinylbenzene-styrene-ethylene terpolymer, the proportion of the ethylene may be about 40 mol % to 80 mol % (mole %), the proportion of the styrene may be about 20 mol % to 60 mol %, the proportion of the divinylbenzene may be about 0.01 mol % to 10 mol %, and the total molar amount of the divinylbenzene, the styrene, and the ethylene is 100 mol %. In other embodiments, in the raw materials for polymerization reaction of the divinylbenzene-styrene-ethylene terpolymer, the proportion of the ethylene may be 40 mol % to 80 mol %, the proportion of the styrene may be 20 mol % to 60 mol %, the proportion of the divinylbenzene may be 0.01 mol % to 1 mol %, and the total molar amount of the divinylbenzene, the styrene, and the ethylene is 100 mol %. In other embodiments, in the raw materials for polymerization reaction of the divinylbenzene-styrene-ethylene terpolymer, the proportion of the ethylene may be about 60 mol % to 80 mol %, the proportion of the styrene may be about 20 mol % to 30 mol %, the proportion of the divinylbenzene may be about 0.01 mol % to 10 mol %, and the total molar amount of the divinylbenzene, the styrene, and the ethylene is 100 mol %. In other embodiments, in the raw materials for polymerization reaction of the divinylbenzene-styrene-ethylene terpolymer, the proportion of the ethylene may be 60 mol % to 80 mol %, the proportion of the styrene may be 20 mol % to 30 mol %, the proportion of the divinylbenzene may be 0.01 mol % to 1 mol %, and the total molar amount of the divinylbenzene, the styrene, and the ethylene is 100 mol %. In other embodiments, in the raw materials for polymerization reaction of the divinylbenzene-styrene-ethylene terpolymer, the proportion of the ethylene may be about 70 mol % to 80 mol %, the proportion of the styrene may be about 20 mol % to 30 mol %, the proportion of the divinylbenzene may be about 0.01 mol % to 1 mol %, and the total molar amount of the divinylbenzene, the styrene, and the ethylene is 100 mol %.

In one embodiment, in Formula (1), each of R₁, R₂, R₃, and R₄ is independently a methylene, an ethylidene, an isobutylidene, or a hydrogen atom. The compound represented by Formula (1) initiates polymerization reaction by the free radicals generated from the cleavage of a carbon-carbon bond of two carbon atoms, each of which connects a benzene ring. For example, the compound represented by Formula (1) may be a compound represented by Formula (2), Formula (3), or Formula (4). For example, the compound represented by Formula (1) may be 2,3-dimethyl-2,3-diphenylbutane, 3,4-dimethyl-3,4-diphenylhexane or 2,7-dimethyl-4,5-diethyl-4,5-diphenyloctane.

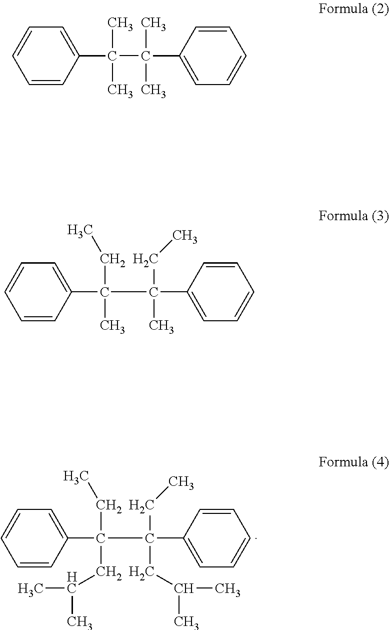

In one embodiment, the resin composition may further comprise a polyolefin other than the divinylbenzene-styrene-ethylene terpolymer, a bis(vinylphenyl)ethane, a maleimide resin, a triallyl isocyanurate, a triallyl cyanurate, a styrene maleic anhydride copolymer resin, a phenol resin, a benzoxazine resin, a cyanate ester resin, a polysiloxane resin, a polyester resin, an epoxy resin, a polyamide resin, or a polyimide resin.

In one embodiment, the resin composition may further include 1 part by weight to 30 parts by weight of the polyolefin other than the divinylbenzene-styrene-ethylene terpolymer, with respect to 100 parts by weight of the vinyl group-containing polyphenylene ether resin, but this disclosure is not limited thereto. In another embodiment, when the resin composition includes a polyolefin other than the divinylbenzene-styrene-ethylene terpolymer, the amount of the polyolefin may be 1 part by weight to 30 parts by weight, 1 part by weight to 15 parts by weight, or 1 part by weight to 10 parts by weight. However, this disclosure is not limited thereto, and the amount of the polyolefin may be adjusted as needed. Besides, the polyolefin other than the divinylbenzene-styrene-ethylene terpolymer may include vinyl group-containing polyolefin or hydrogenated polyolefin.

In one embodiment, the resin composition may further include a vinyl group-containing polyolefin other than the divinylbenzene-styrene-ethylene terpolymer, and the amount of the vinyl group-containing polyolefin is not limited. In another embodiment, the resin composition may further include 1 part by weight to 30 parts by weight of the vinyl group-containing polyolefin, with respect to 100 parts by weight of the vinyl group-containing polyphenylene ether resin, but this disclosure is not limited thereto. In still another embodiment, the resin composition may not include a vinyl group-containing polyolefin other than the divinylbenzene-styrene-ethylene terpolymer. That is, the amount of the vinyl group-containing polyolefin other than the divinylbenzene-styrene-ethylene terpolymer is 0 part by weight, which means that the vinyl group-containing polyolefin other than the divinylbenzene-styrene-ethylene terpolymer is not specifically added into the resin composition herein. The type of the vinyl group-containing polyolefin is not limited, and may include various vinyl group-containing olefin polymers known in the field other than the divinylbenzene-styrene-ethylene terpolymer. For example, the vinyl group-containing olefin polymer may include but not limited to polybutadiene, polyisoprene, styrene-butadiene copolymer, styrene-isoprene copolymer, styrene-butadiene-divinylbenzene terpolymer, styrene-butadiene-maleic anhydride terpolymer, vinyl-polybutadiene-urethane oligomer, or maleic anhydride-butadiene copolymer.

In one embodiment, the resin composition may further include a styrene-butadiene-divinylbenzene terpolymer resin. In another embodiment, the resin composition may not include a styrene-butadiene-divinylbenzene terpolymer resin. That is, the amount of the styrene-butadiene-divinylbenzene terpolymer resin is 0 part by weight, which means that the styrene-butadiene-divinylbenzene terpolymer resin is not specifically added into the resin composition herein.

In one embodiment, the resin composition may further include a hydrogenated polyolefin, and the amount of the hydrogenated polyolefin is not limited. In another embodiment, the resin composition may further include 1 part by weight to 30 parts by weight of the hydrogenated polyolefin, with respect to 100 parts by weight of the vinyl group-containing polyphenylene ether resin, but this disclosure is not limited thereto. In still another embodiment, the resin composition may not include a hydrogenated polyolefin. That is, the amount of the hydrogenated polyolefin is 0 part by weight, which means that the hydrogenated polyolefin is not specifically added into the resin composition herein. The type of the hydrogenated polyolefin is not limited, and may include various hydrogenated styrene-butadiene-styrene block copolymers (or styrene-ethylene/butene-styrene copolymers) known in the field. The hydrogenated polyolefin applicable to the present disclosure is not particularly limited, and may be any one or more of commercial products or homemade products. For example, the hydrogenated polyolefin may include but not limited to hydrogenated styrene-butadiene-styrene block copolymer or maleic anhydride-substituted hydrogenated styrene-butadiene-styrene block copolymer. That is, the hydrogenated polyolefin may include but not limited to unsubstituted hydrogenated styrene-butadiene-styrene triblock copolymer or maleic anhydride-substituted hydrogenated styrene-butadiene-styrene triblock copolymer e. For example, the hydrogenated polyolefin may be products H1221, H1062, H1521, H1052, H1041, H1053, H1051, H1517, H1043, N504, H1272, M1943, M1911, and M1913 available from Asahi KASEI Corp; products G1650, G1651, G1652, G1654, G1657, G1726, FG1901, and FG1924 available from KRATON Corp; or products 8004, 8006, 8007L available from Kuraray.

In one embodiment, the resin composition may further include bis(vinylphenyl)ethane, and the amount of the bis(vinylphenyl)ethane is not limited. In another embodiment, the resin composition may further include 1 part by weight to 35 parts by weight of the bis(vinylphenyl)ethane, with respect to 100 parts by weight of the vinyl group-containing polyphenylene ether resin, but this disclosure is not limited thereto. In still another embodiment, the resin composition may not include bis(vinylphenyl)ethane. That is, the amount of the bis(vinylphenyl)ethane is 0 part by weight, which means that the bis(vinylphenyl)ethane is not specifically added into the resin composition herein. In one embodiment, when the resin composition includes bis(vinylphenyl)ethane, the amount of the bis(vinylphenyl)ethane may be 1 part by weight to 35 parts by weight, 5 parts by weight to 35 parts by weight, or 10 parts by weight to 35 parts by weight. However, this disclosure is not limited thereto, and the amount of the bis(vinylphenyl)ethane may be adjusted as needed.

In one embodiment, the resin composition may further include a maleimide resin, and the amount of the maleimide resin is not limited. In another embodiment, the resin composition may further include 1 part by weight to 30 parts by weight of the maleimide resin, with respect to 100 parts by weight of the vinyl group-containing polyphenylene ether resin, but this disclosure is not limited thereto. In still another embodiment, the resin composition may not include a maleimide resin. That is, the amount of the maleimide resin is 0 part by weight, which means that the maleimide resin is not specifically added into the resin composition herein. In still one embodiment, when the resin composition includes maleimide resin, the amount of the maleimide resin may be 1 part by weight to 30 parts by weight, 1 part by weight to 20 parts by weight, 1 part by weight to 15 parts by weight, or 5 parts by weight to 10 parts by weight. However, this disclosure is not limited thereto, and the amount of the maleimide resin may be adjusted as needed.

In one embodiment, the maleimide resin may include 4,4′-diphenylmethane bismaleimide, polyphenylmethane maleimide (or oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, vinyl benzyl maleimide, biphenyl-containing maleimide, maleimide resin containing an aliphatic long chain structure, a prepolymer of diallyl compound and maleimide resin, a prepolymer of multi-functional amine and maleimide resin, or a prepolymer of aminophenol and maleimide resin.

For example, specific examples of the maleimide resin may include but not limited to products BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 and BMI-7000H available from Daiwakasei Industry Co., Ltd.; products BMI-70, BMI-80 available from K.I Chemical Industry Co., Ltd.; or products MIR-3000 or MIR-5000 available from Nippon Kayaku.

For example, specific examples of the maleimide resin containing an aliphatic long chain structure may include but not limited to products BMI-689, BMI-1400, BMI-1500, BMI-1700, BMI-2500, BMI-3000, BMI-5000 and BMI-6000 available from Designer Molecules Inc.

In one embodiment, the resin composition may further include triallyl isocyanurate. In another embodiment, the resin composition may not include triallyl isocyanurate. That is, the amount of the triallyl isocyanurate is 0 part by weight, which means that the triallyl isocyanurate is not specifically added into the resin composition herein. In still one embodiment, when the resin composition includes triallyl isocyanurate, the amount of the triallyl isocyanurate may bel part by weight to 20 parts by weight, 1 part by weight to 15 parts by weight, or 1 part by weight to 10 parts by weight. However, this disclosure is not limited thereto, and the amount of the triallyl isocyanurate may be adjusted as needed.

In one embodiment, in the styrene maleic anhydride copolymer resin (or styrene maleic anhydride resin), the ratio of the styrene and the maleic anhydride may be 1:1, 2:1, 3:1, 4:1, 6:1, or 8:1. Specific examples of the styrene maleic anhydride copolymer resin may include but not limited to products SMA-1000, SMA-2000, SMA-3000, EF-30, EF-40, EF-60, and EF-80 available from Cray Valley, or products C400, C500, C700, and C900 available from Polyscope. The styrene maleic anhydride resin may be esterified styrene maleic anhydride copolymer, such as SMA1440, SMA17352, SMA2625, SMA3840, and SMA31890 available from Cray Valley.

If not specified, the styrene maleic anhydride resin may be individually or in combination added into the resin composition according to one embodiment of this disclosure. In one embodiment, when the resin composition includes styrene maleic anhydride resin, the amount of the styrene maleic anhydride resin may be 1 part by weight to 20 parts by weight, 1 part by weight to 10 parts by weight, or 1 part by weight to 5 parts by weight. In another embodiment, the resin composition may not include styrene maleic anhydride resin. That is, the amount of the styrene maleic anhydride resin is 0 part by weight. However, this disclosure is not limited thereto, and the amount of the styrene maleic anhydride resin may be adjusted as needed.

In one embodiment, the benzoxazine resin may be bisphenol A benzoxazine resin, bisphenol F benzoxazine resin, phenolphthalein benzoxazine resin, dicyclopentadiene benzoxazine resin, or phosphorus-containing benzoxazine resin, such as product LZ-8270 (phenolphthalein benzoxazine resin), LZ-8280 (bisphenol F benzoxazine resin), and LZ-8290 (bisphenol A benzoxazine resin) available from Huntsman, or product HFB-2006M available from Showa High Polymer. In another embodiment, when the resin composition includes benzoxazine resin, the amount of the benzoxazine resin may be 1 part by weight to 10 parts by weight, 1 part by weight to 5 parts by weight, or 1 part by weight to 3 parts by weight. In still another embodiment, the resin composition may not include benzoxazine resin. That is, the amount of the benzoxazine resin is 0 part by weight. However, this disclosure is not limited thereto, and the amount of the benzoxazine resin may be adjusted as needed.

In one embodiment, the cyanate ester resin may be various cyanate ester resins known in the field, wherein the cyanate ester resin may include but not limited to cyanate ester resins having Ar—O—C—N structure (where Ar is an aromatic group, such as benzene, naphthalene, or anthracene), phenol novolac cyanate ester resin, bisphenol A cyanate ester resin, bisphenol A novolac cyanate ester resin, bisphenol F cyanate ester resin, bisphenol F novolac cyanate ester resin, dicyclopentadiene-containing cyanate ester resin, naphthalene-containing cyanate ester resin, or phenolphthalein cyanate ester resin. Specific examples of the cyanate ester resin may include but not limited to products Primaset PT-15, PT-30S, PT-60S, BA-200, BA-230S, BA-3000S, BTP-2500, BTP-6020S, DT-4000, DT-7000, ULL950S, HTL-300, CE-320, LVT-50, and LeCy available from Lonza. In another embodiment, when the resin composition includes cyanate ester resin, the amount of the cyanate ester resin may be 1 part by weight to 10 parts by weight, 1 part by weight to 5 parts by weight, or 1 part by weight to 3 parts by weight. In still another embodiment, the resin composition may not include cyanate ester resin. That is, the amount of the cyanate ester resin is 0 part by weight. However, this disclosure is not limited thereto, and the amount of the cyanate ester resin may be adjusted as needed.

In one embodiment, the resin composition may further include a polysiloxane resin (abbreviated as polysiloxane hereinafter). In another embodiment, the resin composition may not include a polysiloxane, that is, the amount of the polysiloxane is 0 part by weight, which means that the polysiloxane is not specifically added into the resin composition herein. In still another embodiment, when the resin composition includes polysiloxane, the amount of the polysiloxane may be 5 parts by weight to 30 parts by weight, such as 5 parts by weight, 10 parts by weight or 15 parts by weight. However, this disclosure is not limited thereto, and the amount of the polysiloxane may be adjusted as needed. Specific examples of the polysiloxane may include but not are limited to products X-22-161A, X-22-161B, X-22-163A, X-22-163B, and X-22-164 available from Shin-Etsu Chemical Co., Ltd.

In one embodiment, the resin composition may further include an inorganic filler, solvent, silane coupling agent, flame retardant, coloring agent, toughening agent, or core-shell rubber. These components can be individually or in combination used.

In one embodiment, the resin composition may further include an inorganic filler, and the amount of the inorganic filler is not limited. In another embodiment, the resin composition may further include 30 parts by weight to 130 parts by weight of the inorganic filler, 50 parts by weight to 130 parts by weight of the inorganic filler, or 65 parts by weight to 125 parts by weight of the inorganic filler, with respect to 100 parts by weight of the vinyl group-containing polyphenylene ether resin. However, this disclosure is not limited thereto, and the amount of the inorganic filler may be adjusted as needed.

In one embodiment, the inorganic filler may be silica. In one embodiment, the inorganic filler may be spherical silica. The spherical silica may include various spherical silica known in the field, and the particle size distribution D50 of the spherical silica may be less than or equal to 2.0 m. For example, the particle size distribution D50 is preferably between 0.2 m and 2.0 μm, such as but not limited to 0.2 μm, 0.3 μm, 0.4 μm, 0.6 μm, 0.8 μm, 1.2 μm, 1.3 μm, and 2.0 km. If not specified, the particle size distribution D50 refers to the particle size of the filler (such as but not limited to spherical silica) measured by laser scattering when the cumulative volume percentage reaches 50%. The spherical silica applicable to this disclosure is not particularly limited, and may be any one or more of commercially available products, such as but not limited to the spherical silica available from Admatechs.

In one embodiment, the spherical silica may optionally be pretreated with siloxane as needed. The siloxane includes amino silane, epoxide silane, vinyl silane, ester silane, hydroxyl silane, isocyanate silane, methacryloyloxyl silane, or acryloyloxyl silane. With respect to 100 parts by weight of the spherical silica, the amount of the siloxane for the pretreatment may be 0.005 parts by weight to 0.5 parts by weight, and not limited thereto. The amount of the siloxane is not particularly limited. The additive amount of the siloxane can be adjusted according to the dispersity of the inorganic filler in the resin composition.

In one embodiment, the inorganic filler in the resin composition may be an inorganic filler different from the spherical silica. The amount of the inorganic filler different from the spherical silica may be 5 parts by weight to 100 parts by weight, or 10 parts by weight to 80 parts by weight. However, this disclosure is not limited thereto, the amount of the inorganic filler different from the spherical silica may be adjusted as needed.

In one embodiment, the inorganic filler different from the spherical silica includes non-spherical silica (i.e. irregular silica known in the field, where irregular means not spherical), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, or calcined kaolin. Besides, other than the non-spherical silica, the rest of the inorganic fillers may be spherical, fibrous, plate, particulate, flake or whisker. The inorganic filler different from the spherical silica may be optionally pretreated with siloxane as needed. The example and the amount of the siloxane for pretreating the inorganic filler are the same as described above, and are not repeated herein.

In one embodiment, the resin composition may further include an inhibitor, and the amount of the inhibitor is not limited. In another embodiment, the resin composition may further include 0.01 part by weight to 0.5 parts by weight of the inhibitor, with respect to 100 parts by weight of the vinyl group-containing polyphenylene ether resin, but this disclosure is not limited thereto. In still another embodiment, the resin composition may not include an inhibitor. That is, the amount of the inhibitor is 0 part by weight, which means that the inhibitor is not specifically added into the resin composition herein. In still one embodiment, when the resin composition includes an inhibitor, the amount of the inhibitor may be 0.01 part by weight to 0.5 parts by weight, such as 0.02 parts by weight, 0.05 parts by weight, 0.2 parts by weight, 0.3 parts by weight, 0.45 parts by weight, or 0.5 parts by weight. However, this disclosure is not limited thereto, and the amount of the inhibitor may be adjusted as needed.

If not specified, the inhibitor in the resin composition may be any one or more of the inhibitors applicable to the production of a prepreg, a resin film, a laminate, or a printed circuit board. The inhibitors may include various molecule type polymerization inhibitors or stable free radical type polymerization inhibitors known in the field. The molecule type polymerization inhibitors may include but not limited to phenols, quinones, arylamines, arene nitro compounds, sulfur-containing compounds, or chlorides of metal with variable valency. Specifically, the molecule type polymerization inhibitors may include but not limited to phenol, hydroquinone, 4-tert-butylcatechol, benzoquinone, chloroquinone, 1,4-naphthoquinone, trimethylquinone, aniline, nitrobenzene, Na₂S, FeCl₃, or CuCl₂. The stable free radical type polymerization inhibitors may include but not limited to 1,1-diphenyl-2-picrylhydrazyl radical (DPPH), triphenylmethyl radical, 2,2,6,6-tetramethylpiperidine-1-oxide, or the derivatives of 2,2,6,6-tetramethylpiperidine-1-oxide.

In one embodiment, the resin composition may further include a flame retardant. In another embodiment, the resin composition may not include a flame retardant. That is, the amount of the flame retardant is 0 part by weight, which means that the flame retardant is not specifically added into the resin composition herein. In still another embodiment, when the resin composition includes a flame retardant, the amount of the flame retardant may be 30 parts by weight to 90 parts by weight, such as 30 parts by weight, 40 parts by weight, 50 parts by weight, 60 parts by weight, 70 parts by weight, 80 parts by weight, or 90 parts by weight. However, this disclosure is not limited thereto, and the amount of the flame retardant may be adjusted as needed.

If not specified, the flame retardant in the resin composition may be any one or more of the flame retardants applicable to the production of a prepreg, a resin film, a laminate, or a printed circuit board, such as but not limited to phosphorus-containing flame retardant. For example, the phosphorus-containing flame retardant may include ammonium polyphosphate, hydroquinone bis(diphenyl phosphate), bisphenol A bis(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate), RDXP (such as commercially available PX-200, PX-201, PX-202), phosphazene (such as commercially available SPB-100, SPH-100, SPV-100), melamine polyphosphate, 9,10-dihydro-9-oxa-10-phosphaphenanthrene-10-oxide (DOPO) and its derivatives (such as di-DOPO compounds) or resins (such as DOPO-HQ, DOPO-NQ, DOPO-PN, DOPO-BPN), DOPO epoxy resin, diphenylphosphine oxide (DPPO) and its derivatives (such as di-DPPO compounds) or resins, melamine cyanurate, tri-hydroxyethyl isocyanurate or aluminium phosphinate (such as commercially available OP-930, OP-935). Among them, DOPO-PN is a DOPO-containing phenol novolac resin, and DOPO-BPN may be a bisphenol novolac resin such as DOPO-BPAN (DOPO-bisphenol A novolac), DOPO-BPFN (DOPO-bisphenol F novolac), or DOPO-BPSN (DOPO-bisphenol S novolac).

In one embodiment, the amount of the coloring agent, the toughening agent or core-shell rubber in the resin composition may be individually 0.01 part by weight to 10 parts by weight, such as but not limited to 0.01 part by weight to 3 parts by weight, or 0.05 parts by weight to 1 part by weight. However, this disclosure is not limited thereto, and the amount of these components may be adjusted as needed.

The purpose of adding solvent to the resin composition according to the present disclosure is to dissolve the components in the resin composition so as to change the solid content of the resin composition and to adjust the viscosity of the resin composition. For example, the solvent may include but not limited to methanol, ethanol, ethylene glycol monomethyl ether, acetone, butanone (i.e., methyl ethyl ketone), methyl isobutyl ketone, cyclohexanone, toluene, xylene, methoxyethyl acetate, ethoxyethyl acetate, propoxyethyl acetate, ethyl acetate, propylene glycol methyl ether, dimethyl formamide, dimethyl acetamide, N-methylpyrrolidone, or a combination thereof. The additive amount of the solvent is not particularly limited. The additive amount of the solvent can be adjusted according to the viscosity of the resin composition. In the case of adding the solvent into the resin composition, the solvent will be evaporated when the resin composition is heated to a semi-cured state at a high temperature. Therefore, there is no solvent in the prepreg or the resin film, or there is a small amount of the solvent in the prepreg or the resin film.

If not specified, the coloring agent applicable to the present disclosure may include but not limited to dye or pigment.

The purpose of the toughening agent used herein is to improve the toughness of the resin composition. If not specified, the toughening agent applicable to the present disclosure may include but not limited to carboxyl-terminated butadiene acrylonitrile rubber (CTBN).

If not specified, the core-shell rubber applicable to the present disclosure may include commercially available various core-shell rubbers.

The resin composition in one embodiment of this disclosure may be made into various articles including but not limited to a prepreg, a resin film, a laminate, or a printed circuit board by various processing ways.

For example, the resin composition in one embodiment of this disclosure may be made into a prepreg. The prepreg may include a reinforcement material and a layered structure disposed thereon. The layered structure may be obtained by heating the resin composition at high temperature to a semi-cured state (B-stage). The baking temperature for making the prepreg may be between 120° C. and 150° C., preferably between 120° C. and 130° C., and the baking time may be 3 to 6 minutes. The reinforcement material may be any one of fiber material, woven fabric, and non-woven fabric. The woven fabric preferably includes fiberglass fabrics. The types of the fiberglass fabrics are not particularly limited and may be any commercially available fiberglass fabrics for printed circuit boards, such as E-glass fiber fabric, D-glass fiber fabric, S-glass fiber fabric, T-glass fiber fabric, L-glass fiber fabric, Q-quartz fiber fabric, wherein the types of the fiber may include yarns and rovings, in spread form or standard form. The non-woven fabric preferably includes liquid crystal resin non-woven fabric or quartz non-woven fabric. The liquid crystal resin non-woven fabric may be polyester non-woven fabric, polyurethane non-woven fabric or the like, and not limited thereto. The woven fabric may also include liquid crystal resin woven fabric, such as polyester woven fabric or polyurethane woven fabric or the like, and not limited thereto. The reinforcement materials may increase the mechanical strength of the prepreg. In one preferable embodiment, the reinforcement materials may be optionally pretreated with a siloxane. The prepreg may be further heated and cured to the C-stage to form an insulation layer.

For example, the resin composition in one embodiment of this disclosure may be made into a resin film, which is obtained by heating and baking the resin composition to a semi-cured state. The resin composition may be optionally coated on a polyethylene terephthalate film (PET film), polyimide film (PI film), copper foil or adhesive copper foil, followed by heating and baking to a semi-cured state so as to make the resin composition form into a resin film.

For example, the resin composition in one embodiment of this disclosure may be made into a laminate. For example, the laminate may include at least two metal foils and at least one insulation layer disposed between the two metal foils. The insulation layer may be obtained by curing the resin composition to the C-stage at high temperature and high pressure. The suitable curing temperature is between 220° C. and 260° C., preferably between 230° C. and 260° C., the curing time is 100 to 200 minutes, preferably 120 to 180 minutes, and the suitable pressure is between 400 psi to 600 psi, preferably between 450 psi to 550 psi. The insulation layer may be obtained by curing at least one prepreg or at least one resin film. The material of the metal foil may be copper, aluminum, nickel, platinum, silver, gold or alloy thereof. The metal foil may be a copper foil. In one preferable embodiment, the laminate is a copper-clad laminate.

For example, the metal foil used in the laminate may be hyper very low profile (HVLP) copper foil or hyper very low profile 2 (HVLP2) copper foil, where the surface roughness Rz of the matte side of the HVLP copper foil is less than or equal to 2 μm, and the surface roughness Rz of the matte side of the HVLP2 copper foil is less than or equal to 1.5 m. The definition of the surface roughness Rz is the same as the general definition in the field of copper foil, and is not repeated herein.

For example, in one embodiment, the laminate may be further processed by circuit processing to be made into a printed circuit board. The method of producing the printed circuit board may be any well-known production method.

For example, the articles made from the resin composition in one embodiment of this disclosure may have at least one of the following properties:
a copper foil peeling strength of a copper-containing laminate as measured by reference to IPC-TM-650 2.4.8 of greater than 2.90 lb/in;
a water absorption rate as measured by reference to IPC-TM-650 2.6.2.1a of less than or equal to 0.030%;
a dissipation factor at 10 GHz and room temperature as measured by reference to JIS C2565 of less than or equal to 0.00120; and
a dissipation factor at 10 GHz and room temperature after the article is heated at 125° C. for 200 hours as measured by reference to JIS C2565 of less than or equal to 0.00300.

The chemical raw materials used in the Examples and Comparative Examples in the present disclosure are described as follows:

SA9000: methacrylate-containing polyphenylene ether resin, commercially available.

OPE-2st 2200: vinylbenzyl-containing biphenyl polyphenylene ether resin, commercially available.

OPE-2st 1200: vinylbenzyl-containing biphenyl polyphenylene ether resin, commercially available.

Divinylbenzene-styrene-ethylene terpolymer: the terpolymer of divinylbenzene, styrene, and ethylene, wherein the proportion of the ethylene is 70 mol % to 80 mol %, the proportion of the styrene is 20 mol % to 30 mol %, the proportion of the divinylbenzene is 0.01 mol % to 1 mol %, the total molar amount of the divinylbenzene, the styrene, and the ethylene is 100 mol %, and the number average molecular weight of the divinylbenzene-styrene-ethylene terpolymer is between 5,000 and 15,000, commercially available.

Ricon 257: styrene-butadiene-divinylbenzene terpolymer, commercially available.

Divinylbenzene-styrene-ethylstyrene terpolymer: as described in Synthesis Example 1.

Compound of Formula (2): 2,3-dimethyl-2,3-diphenylbutane, commercially available.

25B: 2,5-dimethyl-2,5-di(t-butylperoxy)-3-hexyne, commercially available.

DCP: dicumyl peroxide, commercially available.

SC2050 SMJ: spherical silica, commercially available.

B-3000: polybutadiene, commercially available.

Ricon 100: styrene-butadiene copolymer, commercially available.

Ricon 150: polybutadiene, commercially available.

Ricon 184MA6: styrene-butadiene-maleic anhydride terpolymer, commercially available.

H1052: hydrogenated styrene-butadiene-styrene block copolymer, commercially available.

bis(vinylphenyl)ethane: commercially available.

BMI-3000: the maleimide resin of Formula (5), commercially available.

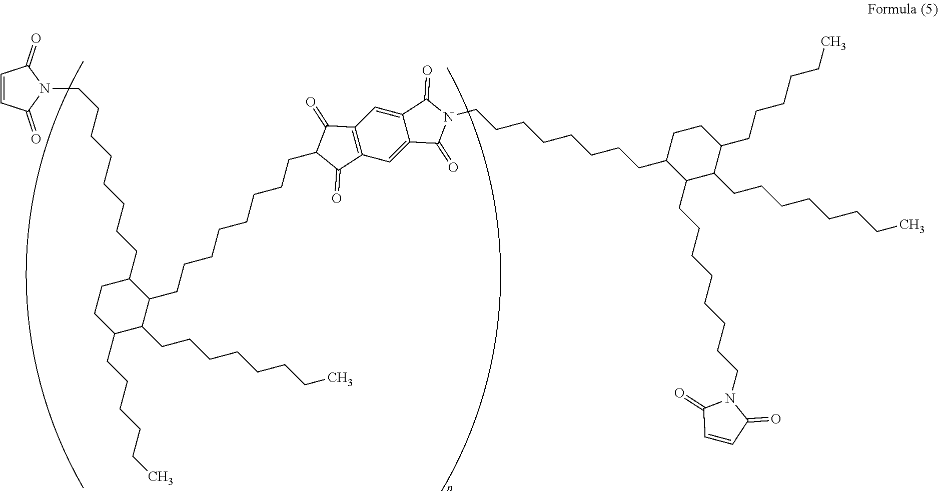

wherein n is a positive integer from 1 to 10.

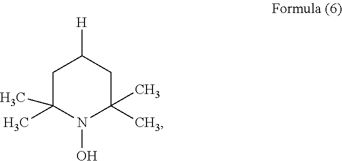

Compound of Formula (6): OH Formula (6), commercially available.

Divinylbenzene: commercially available.

Toluene and butanone: commercially available.

### Synthesis Example 1: Preparation for divinylbenzene-styrene-ethylstyrene terpolymer

3.0 moles (390.6 g) of divinylbenzene, 1.8 moles (229.4 g) of ethylvinylbenzene, 10.2 moles (1066.3 g) of styrene, and 15.0 moles (1532.0 g) of n-propyl acetate are added into a reactor to obtain a polymerization solution. The polymerization solution is stirred continuously to be well-mixed, and heated to 70° C. 600 milli-moles of boron trifluoride diethyl ether complex is added into the polymerization solution, and the polymerization solution is stirred continuously for 4 hours. Sodium hydrogen carbonate aqueous solution is then added into the polymerization solution to stop the polymerization reaction. The oil layer is washed with pure water 3 times, and the volatile components are removed under reduced pressure at 60° C. to obtain divinylbenzene-styrene-ethylstyrene terpolymer.

The raw materials described above are used to prepare for the resin compositions of the examples and the comparative examples of the present disclosure according to the amount disclosed in Table 1 to Table 4, and are further made into various specimens.

TABLE 1
The contents of the resin composition (in part by weight) of Examples E1 to E4.

| substance | component | name | E1 | E2 | E3 | E4 |
|---|---|---|---|---|---|---|
| vinyl group- | methacrylate-containing | SA9000 | 100 | 100 | 100 | 100 |
| containing | polyphenylene | | | | | |
| polyphenylene | ether resin | | | | | |
| ether | vinylbenzyl-containing | OPE-2st 2200 | — | — | — | — |
| | polyphenylene ether resin | OPE-2st 1200 | — | — | — | — |
| divinylbenzene | divinylbenzene-styrene- | | 50 | 20 | 60 | 50 |
| terpolymer | ethylene terpolymer | | | | | |
| | styrene-butadiene- | Ricon 257 | — | — | — | — |
| | divinylbenzene | | | | | |
| | terpolymer | | | | | |
| | divinylbenzene-styrene- | | — | — | — | — |
| | ethylstyrene terpolymer | | | | | |
| initiator | Compound of Formula (2) | | 12 | 12 | 12 | 5 |
| | peroxide | 25B | — | — | — | — |
| | | DCP | — | — | — | — |
| inorganic filler | spherical silica | SC2050 SMJ | 100 | 100 | 100 | 100 |
| polyolefin | polybutadiene | B-3000 | — | — | — | — |
| | styrene-butadiene | Ricon 100 | — | — | — | — |
| | copolymer | | | | | |
| | styrene-butadiene-maleic | Ricon 184MA6 | — | — | — | — |
| | anhydride | | | | | |
| | terpolymer | | | | | |
| | hydrogenated styrene- | H1052 | — | — | — | — |
| | butadiene-styrene | | | | | |
| | block copolymer | | | | | |

| bis(vinylphenyl)ethane | | — | — | — | — |
|---|---|---|---|---|---|
| maleimide resin | BMI-3000 | — | — | — | — |

| Compound of Formula (6) | | — | — | — | — |
|---|---|---|---|---|---|
| solvent | butanone | 60 | 60 | 60 | 60 |
| | toluene | 120 | 120 | 120 | 120 |

| property | unit | E1 | E2 | E3 | E4 |
|---|---|---|---|---|---|
| Dk1 | N/A | 2.75 | 2.78 | 2.74 | 2.76 |
| Df1 | N/A | 0.00104 | 0.00112 | 0.00101 | 0.00106 |
| Dk2 | N/A | 2.76 | 2.79 | 2.74 | 2.77 |
| Df2 | N/A | 0.00233 | 0.00241 | 0.00225 | 0.00239 |
| P/S | lb/in | 2.96 | 3.08 | 2.93 | 2.93 |
| flexural strength | classification | A | A | B | B |
| appearance of | N/A | normal | normal | normal | normal |
| copper-free laminate | | | | | |
| water absorption rate | % | 0.026 | 0.027 | 0.027 | 0.026 |
| glass transition temperature | ° C. | 182 | 192 | 180 | 180 |

TABLE 2
The contents of the resin composition (in part by weight) of Examples E5 to E8.

| substance | component | name | E5 | E6 | E7 | E8 |
|---|---|---|---|---|---|---|
| vinyl group- | methacrylate-containing | SA9000 | 100 | 100 | 80 | 95 |
| containing | polyphenylene | | | | | |
| polyphenylene | ether resin | | | | | |
| ether | vinylbenzyl-containing | OPE-2st 2200 | — | — | 15 | 5 |
| | polyphenylene ether resin | OPE-2st 1200 | — | — | 5 | — |
| divinylbenzene | divinylbenzene-styrene- | | 50 | 25 | 40 | 55 |
| terpolymer | ethylene terpolymer | | | | | |
| | styrene-butadiene- | Ricon 257 | — | — | — | — |
| | divinylbenzene | | | | | |
| | terpolymer | | | | | |
| | divinylbenzene-styrene- | | — | — | — | — |
| | ethylstyrene terpolymer | | | | | |
| initiator | Compound of Formula (2) | | 15 | 12 | 8 | 8 |
| | peroxide | 25B | — | — | — | — |
| | | DCP | — | — | — | — |
| inorganic filler | spherical silica | SC2050 SMJ | 100 | 65 | 90 | 125 |
| polyolefin | polybutadiene | B-3000 | — | — | — | — |
| | styrene-butadiene | Ricon 100 | — | — | — | — |
| | copolymer | | | | | |
| | styrene-butadiene-maleic | Ricon 184MA6 | — | — | 1 | 1 |
| | anhydride | | | | | |
| | terpolymer | | | | | |
| | hydrogenated styrene- | H1052 | — | — | — | 10 |
| | butadiene-styrene | | | | | |
| | block copolymer | | | | | |

| bis(vinylphenyl)ethane | | — | 35 | 22 | 10 |
|---|---|---|---|---|---|
| maleimide resin | BMI-3000 | — | — | 4 | — |

| Compound of Formula (6) | | — | — | — | 0.02 |
|---|---|---|---|---|---|
| solvent | butanone | 60 | 60 | 60 | 60 |
| | toluene | 120 | 120 | 120 | 120 |

| property | unit | E5 | E6 | E7 | E8 |
|---|---|---|---|---|---|
| Dk1 | N/A | 2.73 | 2.71 | 2.72 | 2.75 |
| Df1 | N/A | 0.00102 | 0.00105 | 0.00103 | 0.00101 |
| Dk2 | N/A | 2.75 | 2.72 | 2.73 | 2.75 |
| Df2 | N/A | 0.00229 | 0.00233 | 0.00273 | 0.00239 |
| P/S | lb/in | 3.01 | 2.95 | 3.05 | 3.14 |
| flexural strength | classification | A | B | A | A |
| appearance of | N/A | normal | normal | normal | normal |
| copper-free laminate | | | | | |
| water absorption rate | % | 0.025 | 0.024 | 0.024 | 0.025 |
| glass transition temperature | ° C. | 185 | 217 | 207 | 202 |

TABLE 3
The contents of the resin composition (in part by weight) of Comparative Examples C1 to C5.

| substance | component | name | C1 | C2 | C3 | C4 | C5 |
|---|---|---|---|---|---|---|---|
| vinyl group- | methacrylate-containing | SA9000 | 100 | 100 | 100 | 100 | 100 |
| containing | polyphenylene | | | | | | |
| polyphenylene | ether resin | | | | | | |
| ether | vinylbenzyl-containing | OPE-2st 2200 | — | — | — | — | — |
| | polyphenylene ether resin | OPE-2st 1200 | — | — | — | — | — |
| divinylbenzene | divinylbenzene-styrene- | | — | — | 50 | 50 | 50 |
| terpolymer | ethylene terpolymer | | | | | | |
| | styrene-butadiene- | Ricon 257 | 50 | — | — | — | — |
| | divinylbenzene | | | | | | |
| | terpolymer | | | | | | |
| | divinylbenzene-styrene- | | — | 50 | — | — | — |
| | ethylstyrene terpolymer | | | | | | |
| initiator | Compound of Formula (2) | | 12 | 12 | — | — | — |
| | peroxide | 25B | — | — | 12 | 5 | 0.2 |
| | | DCP | — | — | — | — | — |
| inorganic filler | spherical silica | SC2050 SMJ | 100 | 100 | 100 | 100 | 100 |
| polyolefin | polybutadiene | B-3000 | — | — | — | — | — |
| | styrene-butadiene | Ricon 100 | — | — | — | — | — |
| | copolymer | | | | | | |
| | styrene-butadiene-maleic | Ricon 184MA6 | — | — | — | — | — |
| | anhydride | | | | | | |
| | terpolymer | | | | | | |
| | hydrogenated styrene- | H1052 | — | — | — | — | — |
| | butadiene-styrene | | | | | | |
| | block copolymer | | | | | | |

| bis(vinylphenyl)ethane | | — | — | — | — | — |
|---|---|---|---|---|---|---|
| maleimide resin | BMI-3000 | — | — | — | — | — |

| Compound of Formula (6) | | — | — | — | — | — |
|---|---|---|---|---|---|---|
| solvent | butanone | 60 | 60 | 60 | 60 | 60 |
| | toluene | 120 | 120 | 120 | 120 | 120 |

| property | unit | C1 | C2 | C3 | C4 | C5 |
|---|---|---|---|---|---|---|
| Dk1 | N/A | 2.78 | 2.79 | serious dry | 2.83 | 2.78 |
| Df1 | N/A | 0.00137 | 0.00141 | board, | 0.00197 | 0.00123 |
| Dk2 | N/A | 2.83 | 2.84 | unable to | 2.83 | 2.77 |
| Df2 | N/A | 0.00492 | 0.00515 | test other | 0.00311 | 0.00265 |
| P/S | lb/in | 3.01 | 2.99 | properties | 2.36 | 1.37 |
| flexural strength | classification | A | A | | C | D |
| appearance of | N/A | normal | normal | | dry board | normal |
| copper-free laminate | | | | | | |
| water absorption rate | % | 0.082 | 0.069 | | 0.036 | 0.035 |
| glass transition temperature | ° C. | 210 | 208 | | 184 | 168 |

TABLE 4
The contents of the resin composition (in part by weight) of Comparative Examples C6 to C10.

| substance | component | name | C6 | C7 | C8 | C9 | C10 |
|---|---|---|---|---|---|---|---|
| vinyl group- | methacrylate-containing | SA9000 | 100 | 100 | 100 | 100 | 100 |
| containing | polyphenylene | | | | | | |
| polyphenylene | ether resin | | | | | | |
| ether | vinylbenzyl-containing | OPE-2st 2200 | — | — | — | — | — |
| | polyphenylene ether resin | OPE-2st 1200 | — | — | — | — | — |
| divinylbenzene | divinylbenzene-styrene- | | — | — | 50 | — | — |
| terpolymer | ethylene terpolymer | | | | | | |
| | styrene-butadiene- | Ricon 257 | 50 | — | — | — | — |
| | divinylbenzene | | | | | | |
| | terpolymer | | | | | | |
| | divinylbenzene-styrene- | | — | — | — | — | — |
| | ethylstyrene terpolymer | | | | | | |
| initiator | Compound of Formula (2) | | — | — | — | 12 | 12 |
| | peroxide | 25B | 3 | 3 | — | — | — |
| | | DCP | — | — | 5 | — | — |
| inorganic filler | spherical silica | SC2050 SMJ | 100 | 100 | 100 | 100 | 100 |
| polyolefin | polybutadiene | B-3000 | — | 25 | — | — | — |
| | polybutadiene | Ricon 150 | — | — | — | 15 | — |
| | styrene-butadiene | Ricon 100 | — | 25 | — | — | 25 |
| | copolymer | | | | | | |
| | styrene-butadiene-maleic | Ricon 184MA6 | — | — | — | — | — |
| | anhydride | | | | | | |
| | terpolymer | | | | | | |
| | hydrogenated styrene- | H1052 | — | — | — | — | — |
| | butadiene-styrene | | | | | | |
| | block copolymer | | | | | | |

| bis(vinylphenyl)ethane | | — | — | — | — | — |
|---|---|---|---|---|---|---|
| maleimide resin | BMI-3000 | — | — | — | — | — |

| divinylbenzene | | — | — | — | 20 | 25 |
|---|---|---|---|---|---|---|
| polystyrene | | — | — | — | 15 | — |
| Compound of Formula (6) | | — | — | — | — | — |
| solvent | butanone | 60 | 60 | 60 | 60 | 60 |
| | toluene | 120 | 120 | 120 | 120 | 120 |

| property | unit | C6 | C7 | C8 | C9 | C10 |
|---|---|---|---|---|---|---|
| Dk1 | N/A | 2.81 | 2.81 | 2.82 | 2.78 | 2.79 |
| Df1 | N/A | 0.00147 | 0.00148 | 0.00205 | 0.00125 | 0.00127 |
| Dk2 | N/A | 2.82 | 2.84 | 2.84 | 2.81 | 2.82 |
| Df2 | N/A | 0.00505 | 0.00455 | 0.00325 | 0.00399 | 0.00416 |
| P/S | lb/in | 2.59 | 2.23 | 2.54 | 2.27 | 2.12 |
| flexural strength | classification | C | D | B | B | B |
| appearance of | N/A | dry board | dry board | dry board | patter on | patter on |
| copper-free laminate | | | | | the edge | the edge |
| water absorption rate | % | 0.089 | 0.068 | 0.035 | 0.075 | 0.072 |
| glass transition temperature | ° C. | 211 | 180 | 181 | 183 | 180 |

### Varnish

The components for each Examples (abbreviated as E, such as E1 to E8) or Comparative Examples (abbreviated as C, such as C1 to C10) are added to a stirrer according to the amounts listed in Tables 1 to 4 and stirred and well-mixed to form a resin composition called as a resin varnish.

For example, in Example E1, 100 parts by weight of the SA9000 and 50 parts by weight of the divinylbenzene-styrene-ethylene terpolymer are added into a stirrer containing 120 parts by weight of the toluene solvent and 60 parts by weight of the butanone solvent. The solution is stirred to fully dissolve SA9000 and is well-mixed. Then 12 parts by weight of the compound of Formula (2) is added into the solution. The solution is stirred to fully dissolve it and is well-mixed, followed by adding 100 parts by weight of the SC-2050 SMJ into the solution and stirred continuously to be well-mixed to obtain the varnish of the resin composition E1.

Besides, according to the preparation process of the varnish of Example E1, the varnishes of Examples E2 to E8 and Comparative Examples C1 to C10 are prepared based on the components and their amounts listed in the above Tables 1 to 4.

The specimens made from the varnishes of the Examples E1 to E8 and Comparative Examples C1 to C10 (which are prepreg 1, prepreg 2, copper-clad laminate 1, copper-clad laminate 2, copper-free laminate 1, and copper-free laminate 2, respectively) are prepared as described below and tested for properties under the specified conditions as follows.

### Prepreg 1 (Using 2116 E-Glass Fiber Fabric)

The resin compositions of different Examples (E1 to E8) and Comparative Examples C1 to C10 listed in Tables 1 to 4 are respectively loaded into an impregnation tank. The glass fiber fabric (such as 2116 E-glass fiber fabric) is then immersed into the impregnation tank to adhere the resin composition onto the glass fiber fabric, followed by heating at 130° C. for 4 minutes to a semi-cured stage (B-Stage) to obtain a prepregl (with a resin content of about 56%).

### Prepreg 2 (Using 1035 Q-Quartz Fiber Fabric)

The resin compositions from different Examples (E1 to E8) and Comparative Examples C1 to C10 listed in Tables 1 to 4 are respectively loaded into an impregnation tank. The quartz fiber fabric (such as 1035 Q-quartz fiber fabric) is then immersed into the impregnation tank to adhere the resin composition onto the quartz fiber fabric, followed by heating at 130° C. for 4 minutes to a semi-cured stage (B-Stage) to obtain a prepreg 2 (with a resin content of about 80%).

### Copper-Containing Laminate 1 (or Copper-Clad Laminate 1, Formed by Lamination of Eight Prepreg 1)

Two HVLP2 copper foils with a thickness of 18 m and eight same prepreg 1 are prepared and stacked in the order of the copper foil, the eight prepreg 1 and the copper foil, followed by lamination under vacuum at 500 psi and 235° C. for 150 minutes to form a copper-clad laminate 1.

### Copper-Containing Laminate 2 (or Copper-Clad Laminate 2, Formed by Lamination of Two Prepreg 2)

Two HVLP2 copper foils with a thickness of 18 m and two same prepreg 2 are prepared and stacked in the order of the copper foil, the two prepreg 2 and the copper foil, followed by lamination under vacuum at 500 psi and 235° C. for 150 minutes to form a copper-clad laminate 2.

### Copper-Free Laminate 1 (Formed by Lamination of Eight Prepreg 1)

The copper-clad laminate 1 described above is etched to remove the two copper foils to obtain a copper-free laminate 1, which is formed by lamination of the eight prepreg 1.

### Copper-Free Laminate 2 (Formed by Lamination of Two Prepreg 2)

The copper-clad laminate 2 described above is etched to remove the two copper foils to obtain a copper-free laminate 2, which is formed by lamination of the two prepreg 2.

For the specimens to be tested, the testing method and the properties are described below.

### Copper Foil Peeling Strength (P/S)

The copper-clad laminate 1 (formed by lamination of eight prepreg 1) is cut into a rectangular specimen with a width of 24 mm and a length greater than 60 mm, and then is etched to remove the copper foil on the surface and leave a strip of the copper foil with a width of 3.18 mm and a length greater than 60 mm. The specimen is tested by using a tensile strength tester by reference to IPC-TM-650 2.4.8 at room temperature (about 25° C.) to measure the force (lb/in) required to pull off the copper foil from the surface of the laminate. The higher copper foil peeling strength is better. A difference in the copper foil peeling strength of the specimens greater than or equal to 0.10 lb/in represents a significant difference in copper foil peeling strength in different laminates, which means that there is a significant technical difficulty. The copper foil peeling strength of the copper-clad laminate of Examples (E1 to E8) are greater than 2.90 lb/in, for example, greater than 2.93 lb/in, between 2.90 lb/in and 3.20 lb/in, or between 2.93 lb/in and 3.14 lb/in.

### Dielectric Constant (Dk 1)

In the measurement of dielectric constant, the copper-free laminate 2 (formed by lamination of two prepreg 2) described above is selected as a specimen. Each specimen is measured at 10 GHz at room temperature (25° C.) using a microwave dielectrometer available from AET Corp. by reference to JIS C2565 to obtain the dielectric constant Dk 1 (the dielectric constant Dk 1 and the dissipation factor Df 1 can be simultaneously measured). The lower dielectric constant represents the better dielectric properties of the specimen. At a frequency of 10 GHz, a difference in Dk 1 values of different specimens less than 0.02 represents no significant difference in dielectric constant in different laminates, which means that there is no significant technical difficulty. A difference in Dk 1 values of different specimens greater than or equal to 0.02 represents a significant difference in dielectric constant in different laminates, which means that there is a significant technical difficulty. The dielectric constants Dk 1 of the specimens of Examples (E1 to E8) are between 2.70 and 2.80. For example, the dielectric constants Dk 1 is between 2.71 and 2.78.

Dielectric Constant after Heated (Dk 2)

In the measurement of dielectric constant after heated (Dk 2), the same specimen, the copper-free laminate 2 described above whose dielectric constant Dk 1 is tested, is selected as a specimen. The specimen is placed in a thermostat at a constant temperature of 125° C. for 200 hours, and then the specimen is taken out and cooled to room temperature (25° C.). Next, each specimen is measured at 10 GHz at room temperature (25° C.) using a microwave dielectrometer available from AET Corp. by reference to JIS C2565 to obtain the dielectric constant after heated Dk 2 (abbreviated as dielectric constant Dk2, the dielectric constant Dk 2 and the dissipation factor Df 2 can be simultaneously measured). The lower dielectric constant represents the better dielectric properties of the specimen. At a frequency of 10 GHz, a difference in Dk 2 values of different specimens less than 0.02 represents no significant difference in dielectric constant in different laminates, which means that there is no significant technical difficulty. A difference in Dk 2 values of different specimens greater than or equal to 0.02 represents a significant difference in dielectric constant in different laminates, which means that there is a significant technical difficulty. The dielectric constants Dk 2 of the specimens of Examples (E1 to E8) are between 2.70 and 2.80. For example, the dielectric constants Dk 2 is between 2.72 and 2.79.

### Dissipation Factor (Df 1)

In the measurement of dissipation factor, the copper-free laminate 2 (formed by lamination of two prepreg 2) described above is selected as a specimen. Each specimen is measured at 10 GHz at room temperature (25° C.) using a microwave dielectrometer available from AET Corp. by reference to JIS C2565 to obtain the dissipation factor Df 1 (the dielectric constant Dk 1 and the dissipation factor Df 1 can be simultaneously measured). The lower dissipation factor represents the better dielectric properties of the specimen. At a frequency of 10 GHz, for Df 1 values of different specimens less than or equal to 0.00400, a difference in Df 1 values of less than 0.00010 represents no significant difference in dissipation factor in different laminates, which means that there is no significant technical difficulty. A difference in Df 1 values of different specimens greater than or equal to 0.00010 represents a significant difference in dissipation factor in different laminates, which means that there is a significant technical difficulty. At a frequency of 10 GHz, for Df 1 values of different specimens of greater than 0.00400, a difference in Df 1 values of different specimens less than 0.00050 represents no significant difference in dissipation factor in different laminates. A difference in Df 1 values of different specimens greater than or equal to 0.00050 represents a significant difference in dissipation factor in different laminates. At a frequency of 10 GHz at room temperature, the dissipation factor Df 1 of the specimens of Examples (E1 to E8) are between 0.00100 and 0.00120. For example, the dissipation factors Df 1 are between 0.00101 and 0.00112, and all the dissipation factors Df 1 are less than or equal to 0.00120.

Dissipation Factor after Heated (Df 2)

In the measurement of dissipation factor after heated (Df 2), the same specimen, the copper-free laminate 2 described above, which tests the dissipation factor Df 1, is selected as a specimen. The specimen is placed in a thermostat at a constant temperature of 125° C. for 200 hours, and then the specimen is cooled to room temperature (25° C.). Next, each specimen is measured at 10 GHz at room temperature (25° C.) using a microwave dielectrometer available from AET Corp. by reference to JIS C2565 to obtain the dissipation factor after heated Df 2 (abbreviated as dissipation factor Df 2, the dielectric constant Dk 2 and the dissipation factor Df 2 can be simultaneously measured). The lower dissipation factor represents the better dielectric properties of the specimen. At a frequency of 10 GHz, for Df 2 values of different specimens less than or equal to 0.00400, a difference in Df 2 values of different specimens less than 0.00010 represents no significant difference in dissipation factor in different laminates, which means that there is no significant technical difficulty. A difference in Df 2 values of different specimens greater than or equal to 0.00010 represents a significant difference in dissipation factor in different laminates, which means that there is a significant technical difficulty. At a frequency of 10 GHz, for Df 2 values of different specimens greater than 0.00400, a difference in Df 2 values of different specimens less than 0.00050 represents no significant difference in dissipation factor in different laminates. A difference in Df 2 values of different specimens greater than or equal to 0.00050 represents a significant difference in dissipation factor in different laminates. At a frequency of 10 GHz at room temperature, the dissipation factor Df 2 of the specimens after heated of Examples (E1 to E8) are between 0.00220 and 0.00280. For example, the dissipation factors Df 2 are between 0.00225 and 0.00273, and all the dissipation factors Df 2 are less than or equal to 0.00300.

### Flexural Strength

In the measurement of the flexural strength, each copper-free laminate 2 (formed by lamination of eight prepreg) with a length (the length direction refers to longitudinal direction of the glass fiber fabric) of 3 inches and a width (the width direction refers to latitudinal direction of the glass fiber fabric) of 1 inch is selected as a specimen. Three specimens in each of the examples and the comparative examples are tested, and the average flexural strength of the three specimens are recorded. First, the actual width and thickness (in mm) of each specimen are measured and input into the computer connecting to Universal Tensile Tester. Then, the specimens are individually put onto the carrying platform and are tested by Universal Tensile Tester (AG-5KNX Plus, available from Shimadzu) with a jig (SLBL-5KN, available from Shimadzu) specifically for the flexural strength experiment. When the fracture of the specimen is determined by Universal Tensile Tester, Universal Tensile Tester calculates the maximum load (in N) and the travel distance (in mm) of the jig at which the specimen fractures. The computer connecting to Universal Tensile Tester calculates the flexural strength according to the span length (set at 20 mm) of the tester, the maximum load and the travel distance described above. The flexural strength is calculated by the following formula: Flexural Strength=[(3×maximum loadxspan length)±(2×width of the specimenxsquare of the thickness of the specimen)]. The flexural strength of the specimens of Examples (E1 to E8) are 45,000 lb/(in)² or more, among them, the flexural strength of the specimens of Examples E1, E2, E5, E7, and E8 are 50,000 lb/(in)² or more.

The results and the classifications of the flexural strength:

A level: the flexural strength is greater than or equal to 50,000 (lb/(in)²). For example, the flexural strength is between 50,000 and 55,000 (lb/(in)²).

B level: the flexural strength is between 45,000 and 49,999 (lb/(in)²).

C level: the flexural strength is between 40,000 and 44,999 (lb/(in)²).

D level: the flexural strength is less than or equal to 39,999 (lb/(in)²).

### Appearance of the Copper-Free Laminate

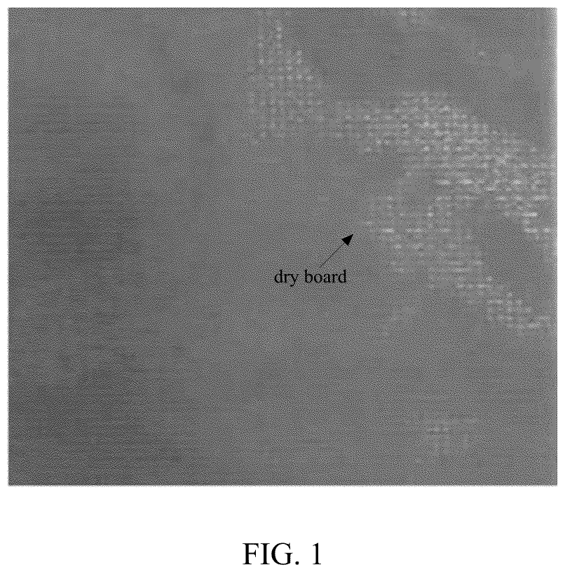

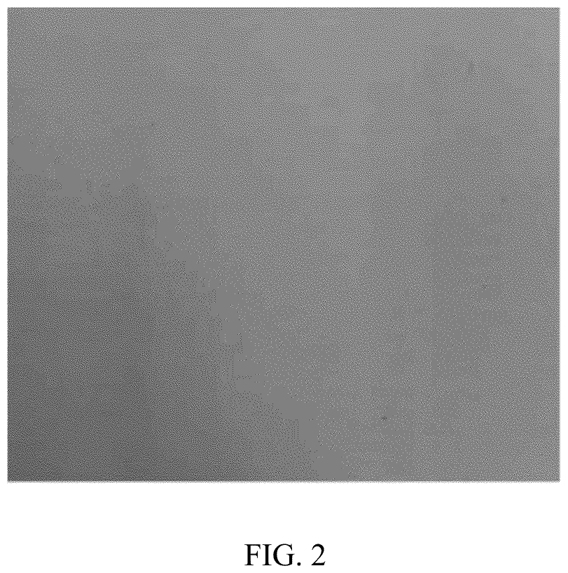

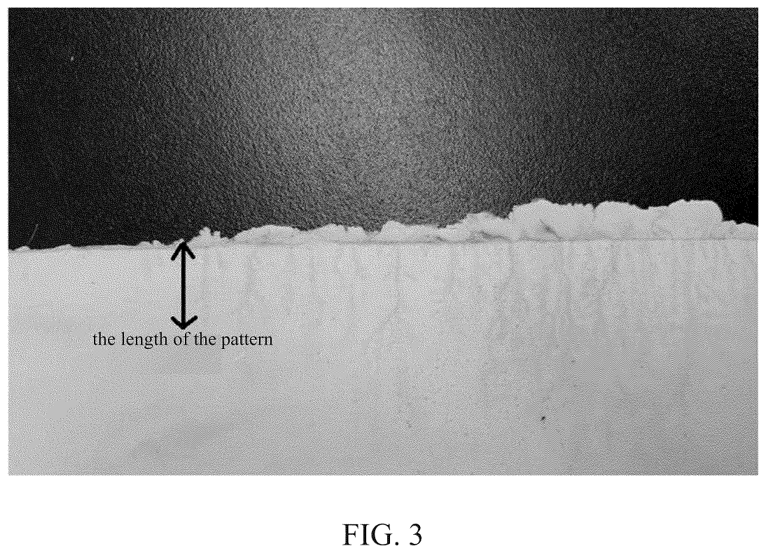

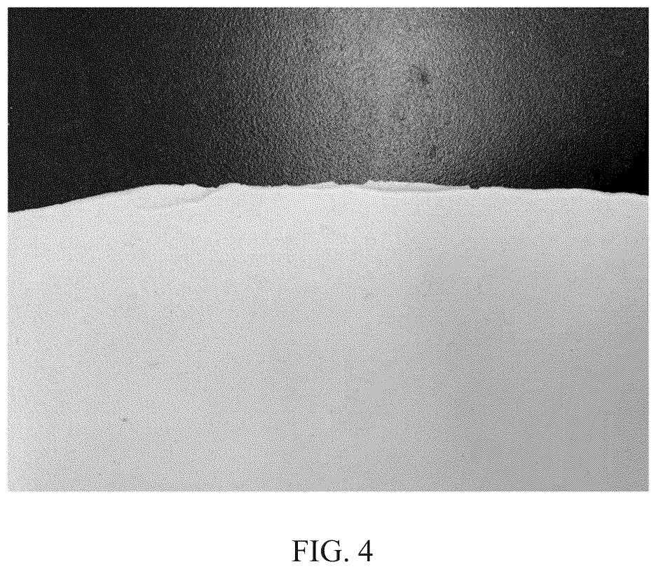

The surface of the insulation layer of the copper-free laminate 1 (formed by lamination of eight prepreg 1) is examined with naked eyes to determine whether a dry board or a branch-like pattern is present on the appearance of the surface of the insulation layer of the copper-free laminate. The dry board is schematically illustrated in FIG. 1. The dry board represents that weave exposure (or starvation of the surface of the insulation layer) is present on the surface of the insulation layer of the copper-free laminate 1. The absence of dry board and branch-like pattern on the surface of the insulation layer of the copper-free laminate is schematically illustrated in FIGS. 2 and 4. The presence of the branch-like pattern on the edge of the surface of the insulation layer of the copper-free laminate represents poor compatibility in the resin composition or high flowability variation that causes inhomogeneity. The branch-like pattern is schematically illustrated in FIG. 3. The more branch-like patterns represents that the branch-like phenomenon is more serious. The presence of the branch-like pattern on the edge is recorded when at least one of the patterns examined with naked eyes is greater than or equal to 1 mm. The presence of the distribution of the dry board or the branch-like pattern on the surface of the insulation layer of the copper-free laminate may cause an uneven property (poor reliability) of the subsequently-made circuit board and a significant reduction in yield rate. For example, the disadvantage includes poor dielectric property, low heat resistance, uneven thermal expansion, or poor adhesion between layers. The circuit board having the above disadvantages should be scrapped directly. There is no dry board and branch-like pattern on the appearance of the copper-free laminates of all Examples (E1 to E8).

### Water Absorption Rate

In the measurement of the water absorption rate, the copper-free laminate 1 (formed by lamination of eight prepreg 1) with a length of 2 inches and a width of 2 inches is selected as a specimen. Each specimen is placed in a 105±10° C. oven and baked for 1 hour and then taken out and cooled at room temperature (about 23° C.) for 10 minutes, and then the copper-free laminate 2 is weighed as W1. Next, the copper-free laminate 2 after weighed is immersed into pure water for 24 hours at room temperature, and the water on the surface of the copper-free laminate 2 is wiped out, and then the copper-free laminate 2 is weighed as W2. The water absorption rate (in %) of each specimen as measured by reference to IPC-TM-650 2.6.2.1a is calculated by the following formula:

$$Water Absorption Rate W ( \% ) = [ ( W 2 - W 1 ) / W 1 ] \times 100 \%$$

In the field, the lower water absorption rate is better. A difference in water absorption rate of different specimens of greater than or equal to 0.010% represents a significant difference in water absorption rate in different laminates, which means that there is a significant technical difficulty. For example, the water absorption rate of the article made from the resin composition according to one embodiment of this disclosure measured by reference to IPC-TM-650 2.6.2.1a is less than or equal to 0.030%, for example, between 0.020% and 0.030%.

### Glass Transition Temperature

In the measurement of the glass transition temperature, the copper-free laminate 1 (formed by lamination of eight prepreg 1) described above is selected as a specimen. The glass transition temperature (in ° C.) of the specimens is measured using a dynamic mechanical analysis (DMA) by reference to IPC-TM-650 2.4.24.4. The temperature interval during the measurement was set at 35° C. to 270° C. with a temperature increasing rate of 2° C./minute. The higher glass transition temperature is better. From the dynamic mechanical analysis, the glass transition temperature of the specimens of Examples (E1 to E8) are greater than or equal to 180° C., which means that the copper-free laminate 1 has reached the basic level of the heat resistance of the laminate.

According to the above embodiments, the article made from the resin composition of this disclosure, such as prepreg, resin film, laminate, or printed circuit board, has an excellent property of at least one of the copper foil peeling strength of a copper-containing laminate, water absorption rate, dissipation factor, flexural strength, and glass transition temperature. Therefore, the article can become a high-performance laminate satisfying the comprehensive demands.

Although the present disclosure is disclosed by the above embodiments, it is not intended to limit the present disclosure. Various modifications and variations belong to the scope of the patent claim without departing from the spirit and the scope of the present disclosure. Regarding the scope of the patent claim defined in the present disclosure, please refer to the accompanying claims.

What is claimed is:

1. A resin composition, comprising:
100 parts by weight of a vinyl group-containing polyphenylene ether resin;
20 parts by weight to 60 parts by weight of a divinylbenzene-styrene-ethylene terpolymer; and
5 parts by weight to 15 parts by weight of a compound represented by Formula (1), 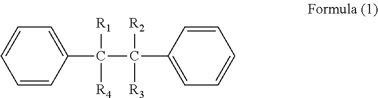
wherein each of R₁, R₂, R₃, and R₄ is independently a C1 to C4 alkylidene group or a hydrogen atom.

2. The resin composition according to claim 1, wherein each of R₁, R₂, R₃, and R₄ is independently a methylene, an ethylidene, an isobutylidene, or a hydrogen atom.

3. The resin composition according to claim 1, wherein the compound represented by Formula (1) is a compound represented by Formula (2), Formula (3), or Formula (4),

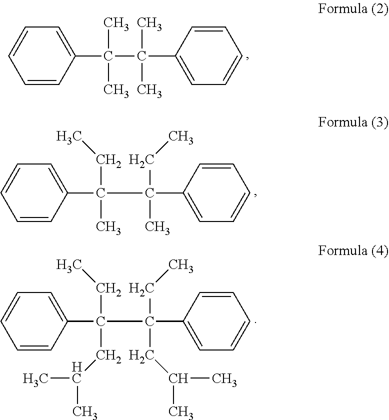

4. The resin composition according to claim 1, wherein the vinyl group-containing polyphenylene ether resin comprises a vinylbenzyl-containing polyphenylene ether resin, a (meth)acrylate-containing polyphenylene ether resin, a vinylbenzyl-containing bisphenol A polyphenylene ether resin, or a maleimide-containing polyphenylene ether resin.

5. The resin composition according to claim 1, wherein a number average molecular weight (Mn) of the divinylbenzene-styrene-ethylene terpolymer is between 5,000 and 15,000.

6. The resin composition according to claim 1, wherein the divinylbenzene-styrene-ethylene terpolymer is obtained by a polymerization reaction of 40 mol % to 80 mol % of an ethylene monomer, 20 mol % to 60 mol % of a styrene monomer, and a 0.01 mol % to 10 mol % of a divinylbenzene monomer, and a total molar amount of the divinylbenzene monomer, the styrene monomer, and the ethylene monomer is 100 mol %.

7. The resin composition according to claim 1, wherein the resin composition further comprises a polyolefin other than the divinylbenzene-styrene-ethylene terpolymer, a bis(vinylphenyl)ethane, a maleimide resin, a triallyl isocyanurate, a triallyl cyanurate, a styrene maleic anhydride copolymer resin, a phenol resin, a benzoxazine resin, a cyanate ester resin, a polysiloxane resin, a polyester resin, an epoxy resin, a polyamide resin, or a polyimide resin.

8. The resin composition according to claim 1, wherein the resin composition further comprises an inorganic filler.

9. An article made from the resin composition according to claim 1, comprising a prepreg, a resin film, a laminate, or a printed circuit board.

10. The article according to claim 9, wherein the article has at least one of the following properties:
a copper foil peeling strength of a copper-containing laminate as measured by reference to IPC-TM-650 2.4.8 of greater than 2.90 lb/in;
a water absorption rate as measured by reference to IPC-TM-650 2.6.2.1a of less than or equal to 0.030%;
a dissipation factor at 10 GHz and room temperature as measured by reference to JIS C2565 of less than or equal to 0.00120; and
a dissipation factor at 10 GHz and room temperature after the article is heated at 125° C. for 200 hours as measured by reference to JIS C2565 of less than or equal to 0.00300.
